(19) United States
(12) Patent Application Publication
(10) Pub. No.: US 2006/0273441 A1
(43) Pub. Date: Dec. 7, 2006

(54) Assembly structure and method for chip scale package

(76) Inventors: Yueh-Chiu Chung, Jhudong Township (TW); Sheng-Chang Lin, Hsin Chu (TW); Chen-Wen Tsai, Hsinchu City (TW)

Correspondence Address: LIN & ASSOCIATES INTELLECTUAL PROPERTY, P.O. BOX 2339, SARATOGA, CA, 95070-0339, US

(21) Appl. No.: 11/144,719

(22) Filed: Jun. 4, 2005

(51) Int. Cl. H01L 23/24

(52) U.S. Cl. 257/687

(57) ABSTRACT

Disclosed is an assembly structure of chip scale package, which can effectively avoid various yield and quality problems resulted from the poor control of epoxy during the process of chip scale package. A buffer zone whose planar size is smaller than that of the chip is disposed on the substrate, and the chip is then affixed to the buffer zone utilizing epoxy. Since the planar size of the buffer zone is smaller than that of the chip, the contamination of golden fingers and bonding pads due to the poor control of epoxy can be avoided, and furthermore the yield problems resulted from failed wire bonding and poor soldering are avoided. The assembly structure can be further applied to vertical stacking of multiple chips. A packaging method for the chip scale package is also provided.

### FIELD OF THE INVENTION

The invention generally relates to chip scale package, and more particularly to an assembly structure and a method for chip scale package so that the epoxy bleeding problem during die attach can be avoided.

### BACKGROUND OF THE INVENTION

Chip scale package (CSP) is referred to packaging processes whose package size lies between 1 to 1.2 times of the chip size. As consumer electronic products are continuously driven for more functionality but with even smaller form factor and lighter weight, chip scale package has become a challenge faced by the entire packaging industry.

FIG. 1a shows a top view of a conventional assembly structure of chip scale package, in which a chip 20 is affixed to a substrate 10 in the die attach stage, and then, in the wire bonding stage, bonding pads 25 on the chip 20 are electrically connected to golden fingers 15 on the substrate 10 through the electrically conductive bonding wires 30, and then finally the chip 20 and the bonding wires 30 are sealed inside a epoxy resin molding compound (not shown in FIG. 1a).

Conventionally, there are two approaches to the die attach of chip scale package, wherein the more matured approach is that the chip is affixed to the substrate utilizing an adhesive such as epoxy. However, during the chip scale packaging process, the epoxy has to be applied precisely, otherwise problems such as epoxy bleeding, and uneven thickness of epoxy will easily occur, which can lead to the contamination of the golden fingers or bonding pads, and the incline of the chip. Furthermore, if epoxy is not precisely controlled, the various yield problems such as chip collapse, chip crack, poor wire bonding, and poor soldering will occur. Therefore, the quality requirement of chip scale package cannot be met. FIG. 1b shows a sectional view of a conventional chip scale package utilizing epoxy for die attach. FIG. 1c is a top view of chip scale package shown in FIG. 1b having the epoxy bleeding problem. It can be seen from FIGS. 1b and 1c that, when the area of the chip 20 is very close to the area of the substrate 10, the golden fingers 15a can be easily contaminated by some traces of the bleeding epoxy 40.

Another more recent approach of die attach is that the chip is affixed to a substrate utilizing a thin film. Although the problems associated with the control of epoxy are avoided, the reliability of the products using this approach is not completely solved.

### SUMMARY OF THE INVENTION

Accordingly, the main objective of the present invention is to provide an assembly structure and a method of chip scale package so that the various yield problems caused by the poor control of epoxy in chip scale packaging process can be effectively avoided.

To achieve the foregoing objective, the present invention provides an assembly structure and a method, which affixes a buffer zone, the planar size of which is smaller than that of the chip, to a substrate utilizing epoxy, then affixes the chip on top of the buffer zone utilizing epoxy, and then conducts the subsequent wire bonding, molding processes. Because the planar size of the buffer zone is smaller than that of the chip, the contamination of golden fingers and bonding pads by the poor control of epoxy is avoided, and furthermore various yield problems such as failed wire bonding and poor soldering can be avoided.

The assembly structure and method provided by the present invention could be further applied to vertically stacking multiple chips utilizing the buffer zone as a separator to increase the density of the package.

The greatest advantage of the present invention lies in that it not only effectively solves the problems of the epoxy control in chip scale packaging, but also allows the use of more matured epoxy-based die attach approach to meet the requirements in production yield and product reliability.

The novel features of the invention are set forth in the appended claims. The invention itself, however, as well as a preferred mode of use, and further objects and advantages thereof, will best be understood by reference to the following detailed description of illustrative embodiments when read in conjunction with the accompanying drawings:

### BRIEF DESCRIPTION OF THE DRAWINGS

FIG. 1a shows a top view of a conventional assembly structure of chip scale package;

FIG. 1b shows a sectional view of a conventional chip scale package utilizing epoxy for the die attach;

FIG. 1c shows a top view of the chip scale package shown in FIG. 1b having epoxy bleeding problem;

FIG. 2a shows a top view of the assembly structure of chip scale package according to an embodiment of the present invention;

FIG. 2b shows a sectional view of the assembly structure of chip scale package shown in FIG. 2a;

FIG. 3a shows a sectional view of the buffer zone according to an embodiment of the present invention;

FIG. 3b is a sectional view of the buffer zone according to another embodiment of the present invention; and

FIG. 4 is a sectional view of the assembly structure of chip scale package according to another embodiment of the present invention.

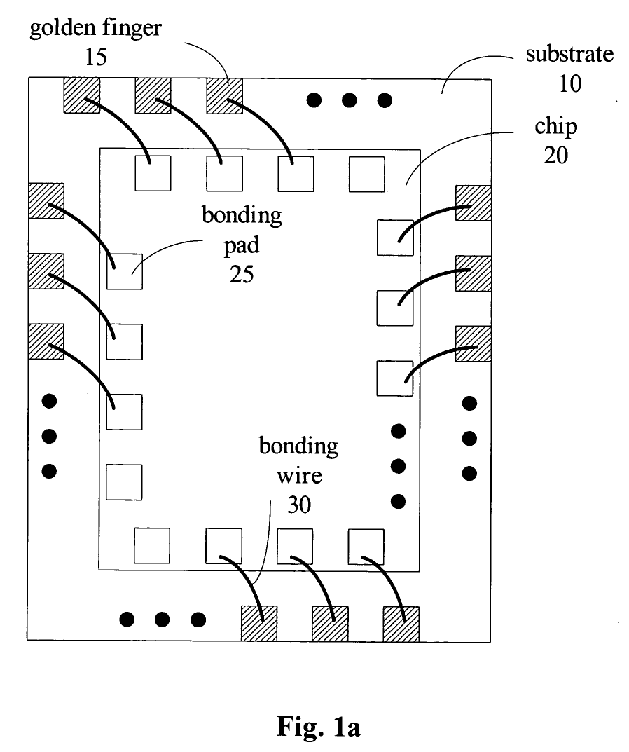

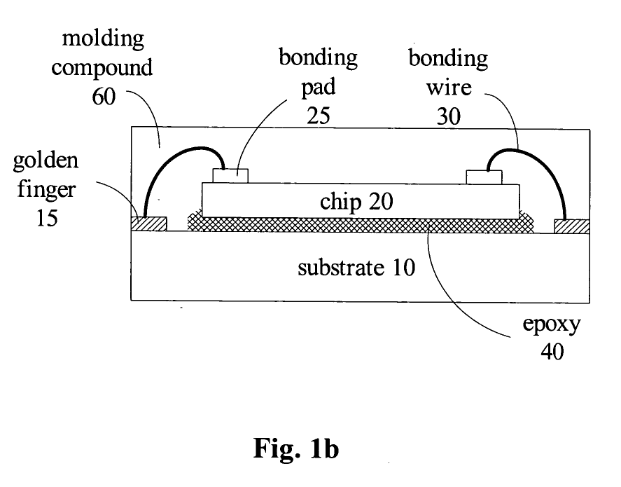

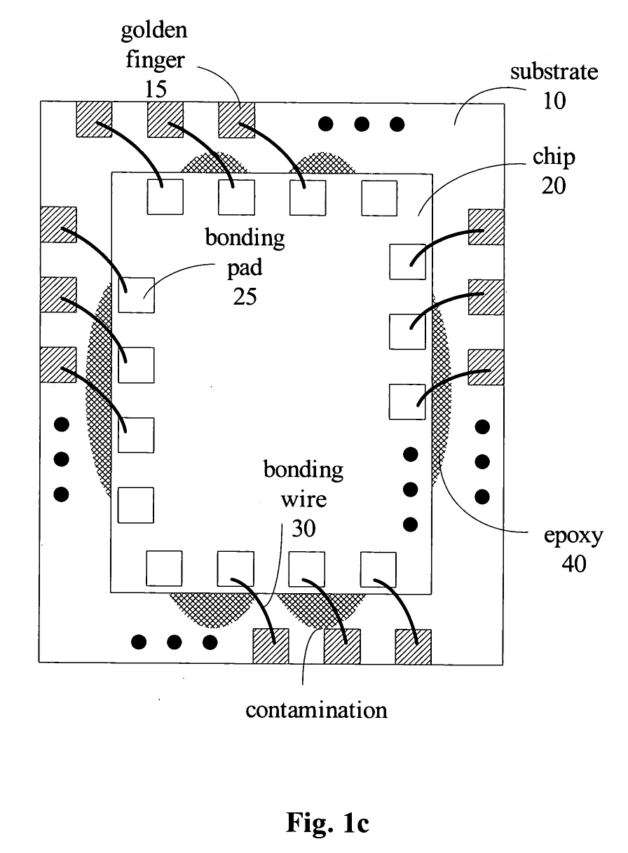

### DETAILED DESCRIPTION OF THE PREFERRED EMBODIMENT

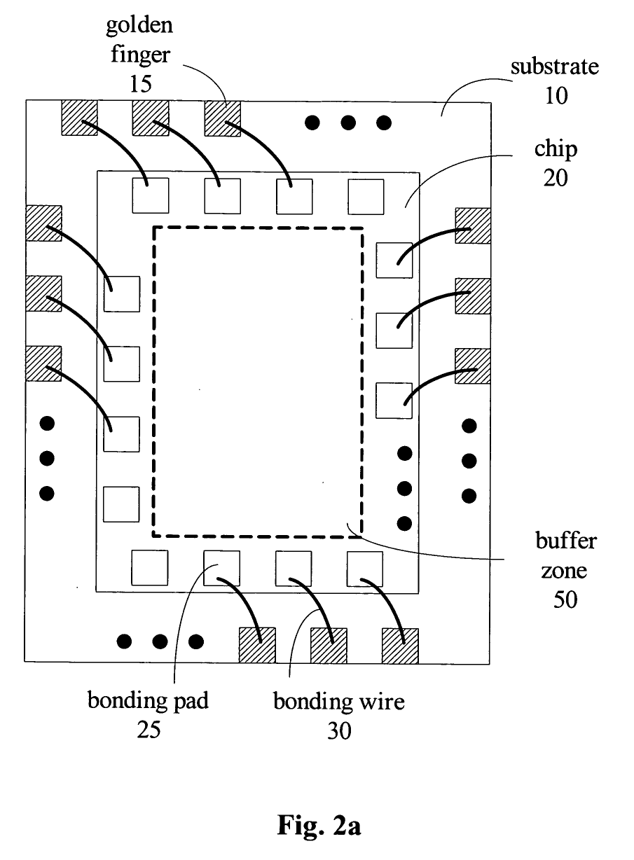

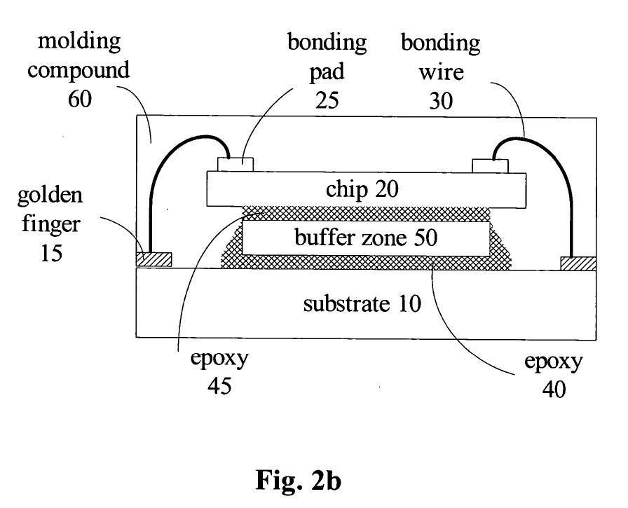

FIG. 2a shows a top view of the assembly structure of chip scale package according to an embodiment of the present invention and FIG. 2b shows a sectional view of the assembly structure of chip scale package shown in FIG. 2a. As shown in FIGS. 2a and 2b, a buffer zone 50 with an appropriate planar size which is smaller than that of a chip 20, is affixed to one side of a substrate 10 utilizing a first adhesive 40 (which is epoxy in this embodiment). Subsequently, the chip 20 is affixed on top of the buffer zone 50 utilizing a second adhesive 45 (which is epoxy in this embodiment). It is noted that the first adhesive 40 and the second adhesive 45 are not only limited to epoxy. Other suitable adhesives can be used in other embodiments. Moreover, the first adhesive 40 and the second adhesive 45 is not necessarily the same.

Subsequently, through the bonding wires 30, the bonding pads 25 of the chip 20 are electrically connected to the golden fingers 15 of the substrate 10, and then finally the chip 20 and the bonding wires 30 are sealed altogether with a molding compound 60 (which is epoxy resin in this embodiment). It is noted that because of the smaller planar size of the buffer zone compared with the chip, more buffer space will be available between the bonding pads 25 of the chip 20 and the golden fingers 15 of the substrate 10. It is noted that other suitable material can be used as a molding compound other than the epoxy resin.

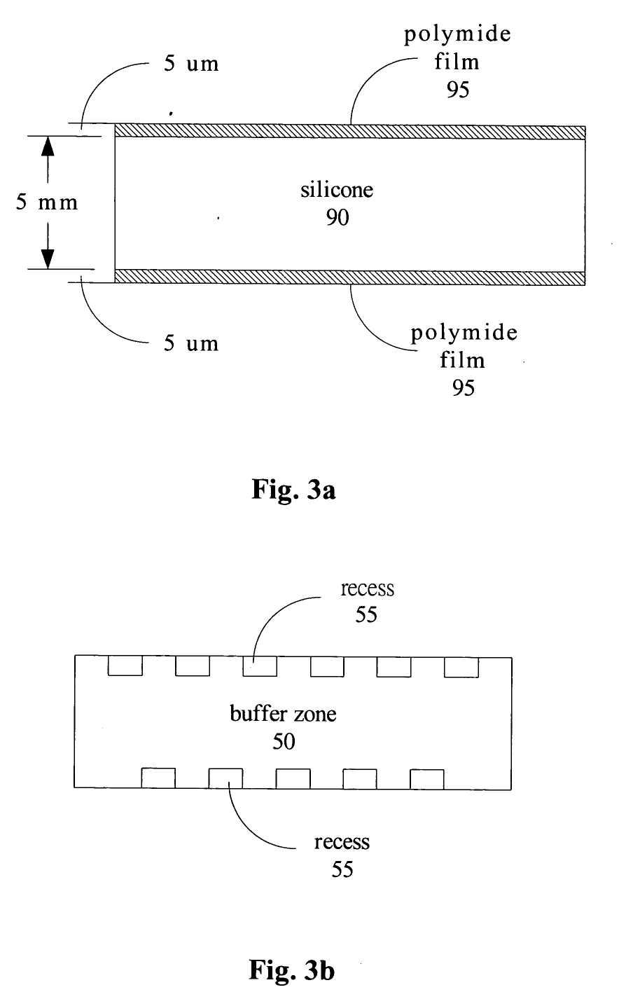

The material of buffer zone 50 can be silicone, or metals whose thermal expansion coefficient close to that of the chip 20 (for avoiding the chip collapse or crack caused by the accumulation of stress due to the different thermal expansion coefficients between the chip 20 and the buffer zone 50). The buffer zone 50 can also be a raw material wafer. Thickness of the buffer zone is generally about 5 mm. Furthermore, the buffer zone 50 can have a structure shown in FIG. 3a, in which each of the upper surface and the lower surface of a silicone layer 90 is coated with a 5 μm-thick polyimide film 95. Furthermore, in order to reduce the accumulated stress between the chip 20 and the buffer zone 50, at least one of the upper surface and the lower surface of the buffer zone 50 has a plurality of recesses 55 etched by MEMS (micro-electron-mechanical-system) methods.

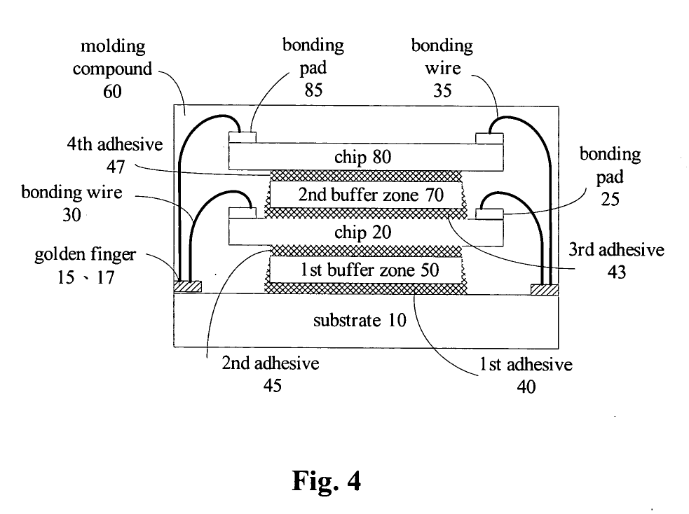

From the foregoing illustration, it can be seen that the present invention uses vertical space in exchange for larger planar space between the chip and the golden fingers of the substrate. Therefore, the present invention is able to adopt the more matured die attach approach (i.e., epoxy) to effectively increase the yield of the chip scale package. The aforementioned assembly structure and method of chip scale package provided by the present invention can be further applied to vertically stacking multiple chips as shown in FIG. 4. As illustrated, a first buffer zone 50 with an appropriate planar size that is smaller than that of a first chip 20 is affixed to one side of a substrate 10 utilizing a first adhesive 40 (which is epoxy in this embodiment). Subsequently, the first chip 20 is affixed on top of the first buffer zone 50 utilizing a second adhesive 45 (which is epoxy in this embodiment). Then, through the bonding wires 30, the bonding pads 25 on the first chip 20 are electrically connected to the golden fingers 15 on the substrate 10. And then a second buffer zone 70 with an appropriate planar size which is smaller than that of a second chip 80 is affixed on top of the first chip 20 utilizing a third adhesive 43. Furthermore, the second chip 80 is affixed to the second buffer zone 70 utilizing a fourth adhesive 47. Moreover, through the bonding wires 35, the bonding pads 85 on the second chip 80 are electrically connected to the golden fingers 17 on the substrate 10. Finally, the first chip 20, the second chip 80, the bonding wires 30 and 35 are all sealed inside a molding compound 60 (which is epoxy resin in this embodiment). It is noted that the materials, thicknesses, and planar sizes of the first buffer zone and the second buffer zone can be different. The first, second, third, fourth adhesives can also be different. The process can be repeated to obtain a stacking of chips more than two layers.

The foregoing description of the embodiments of the invention has been presented for purposes of illustration and description. It is not intended to be exhaustive or to limit the invention to the precise form disclosed. Obvious modifications or variations are possible in light of the above teachings. The embodiments were chosen and described to provide the best illustration of the principles of the invention and its practical application to thereby enable one of ordinary skill in the art to utilize the invention in various embodiments and with various modifications as are suited to the particular use contemplated. All such modifications and variations are within the scope of the invention as determined by the appended claims when interpreted in accordance with the breadth to which they are fairly, legally, and equitably entitled.

What is claimed is:

1. An assembly structure of chip scale package, comprising:
a substrate having a plurality of golden fingers;
a buffer zone affixed to one side of said substrate utilizing a first adhesive;
a chip affixed on top of said buffer zone utilizing a second adhesive, said chip having a plurality of bonding pads;
a plurality of bonding wires each of which is electrically connected to one of said golden fingers and one of said bonding pads; and
a molding compound disposed on said substrate sealing said buffer zone, said chip, and said bonding wires inside,
wherein the planar size of said buffer zone is smaller than the planar size of said chip, and the planar size of said chip is smaller than the planar size of said substrate.

2. The assembly structure of chip scale package as claimed in claim 1, wherein said molding compound is epoxy resin.

3. The assembly structure of chip scale package as claimed in claim 1, wherein said first adhesive is epoxy.

4. The assembly structure of chip scale package as claimed in claim 1, wherein said second adhesive is epoxy.

5. The assembly structure of chip scale package as claimed in claim 1, wherein said buffer zone is made of a material selected from the group consisting of silicone, and a metal with a thermal expansion coefficient close to the thermal expansion coefficient of said chip.

6. The assembly structure of chip scale package as claimed in claim 1, wherein said buffer zone is a raw material wafer.

7. The assembly structure of chip scale package as claimed in claim 1, wherein said buffer zone is a silicone layer, each of whose upper surface and lower surface is coated with a polyimide film respectively.

8. The assembly structure of chip scale package as claimed in claim 1, wherein at least one of the upper surface and the lower surface of said buffer zone has a plurality of recesses.

9. A packaging method of chip scale package comprising the steps of:
providing a substrate having a plurality of golden fingers;
affixing a buffer zone to one side of said substrate utilizing a first adhesive;
affixing a chip on top of said buffer zone utilizing a second adhesive, said chip having a plurality of bonding pads;
electrically connecting said golden fingers to said bonding pads with a plurality of bonding wires; and
disposing a molding compound on said substrate and sealing said buffer zone, said chip, and said bonding wires together inside said molding compound;
wherein the planar size of said buffer zone is smaller than the planar size of said chip, and the planar size of said chip is smaller than the planar size of said substrate.

10. The packaging method as claimed in claim 9, wherein said molding compound is epoxy resin.

11. The packaging method as claimed in claim 9, wherein said first adhesive is epoxy.

12. The packaging method as claimed in claim 9, wherein said second adhesive is epoxy.

13. The packaging method as claimed in claim 9, wherein said buffer zone is made of a material selected from the group consisting of silicone, and a metal with a thermal expansion coefficient close to the thermal expansion coefficient of said chip.

14. The packaging method as claimed in claim 9, wherein said buffer zone is a raw material wafer.

15. The packaging method as claimed in claim 9, wherein said buffer zone is a silicone layer, each of whose upper surface and lower surface is coated with a polyimide film respectively.

16. The packaging method as claimed in claim 9, wherein at least one of the upper surface and the lower surface of said buffer zone has a plurality of recesses.
